(19) United States
(12) Patent Application Publication
(10) Pub. No.: US 2025/0353190 A1
(43) Pub. Date: Nov. 20, 2025

(54) END-EFFECTOR WITH SELF POWERED ELECTROSTATIC CHUCK

(71) Applicant: ASM IP Holding B.V., Almere (NL)

(72) Inventors: Salam Harb, Scottsdale, AZ (US); Paras Shah, Scottsdale, AZ (US); Pradeep Nambiath, Mesa, AZ (US)

(21) Appl. No.: 19/205,642

(22) Filed: May 12, 2025

Related U.S. Application Data
(60) Provisional application No. 63/647,331, filed on May 14, 2024.

(51) Int. Cl. B25J 15/00; H02N 13/00

(52) U.S. Cl. CPC B25J 15/0085; H02N 13/00

(57) ABSTRACT

A vacuum robot includes an end effector comprising an electrostatic chuck and an electrical generator coupled to the end effector to provide a chucking voltage to the end effector to activate the electrostatic chuck. The electrical generator may include generating electrical energy from at least one of: a light source, a laser source, or a set of electrical coils in a magnetic field.

### CROSS-REFERENCE TO RELATED APPLICATION(S)

This application claims priority to and the benefits of U.S. Provisional Patent Application No. 63/647,331, filed May 14, 2024, the contents of which are incorporated herein by reference their entirety.

### FIELD OF INVENTION

The present disclosure generally relates to fabricating semiconductor devices, and more particularly, to handing substrates during the fabrication of substrates.

### BACKGROUND OF THE DISCLOSURE

A process of using a substrate processing apparatus includes a step of transporting a substrate from a Front Opening Unified Pod (FOUP) to a processing chamber via a substrate handling chamber and a load lock chamber using a robotic arm of a vacuum robot, or a step of transporting a substrate from a reaction chamber to another reaction chamber using a robotic arm. The robotic arm may be provided with an end effector for loading a substrate thereon and carrying the substrate from one chamber to another.

In conventional systems, vacuum robots are limited in the transfer speed and hence Throughput (TPT). This is due to the lack of enough griping force to hold wafer stable during high acceleration/speed robot motion. As the throughput is increased, the transferring speed by the robotic arm is also increased. When the transferring speed is increased, since the substrate stays on the end effector by friction, the substrate sometimes moves relative to the end effector and slips out of place, thereby causing a transfer error and decreasing transfer stability. Most systems rely on gravitational and friction forces to constraint wafer during motion. Both of these forces are limited in nature preventing end-users from improving on robot speed. They limit robot speed to prevent wafer slip and hence compromise on TPT.

In conventional systems, an anti-slip end effector having several pins are used to suppress the movement. Further, implementing mechanical mechanisms in a vacuum is a complex process and may also result in particle contamination. A mechanical solution may also involve additional wiring and tubing that would further complicate the transfer process. Accordingly, there is a need in the art for systems and methods that improve the speed of vacuum robot during transfer while preventing wafer slip during transfer without extensive mechanical means that require usage of additional wiring. The present disclosure provides a solution to this need.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

A vacuum robot includes an end effector that includes an electrostatic chuck. The vacuum robot further includes an electrical generator coupled to the end effector to provide a chucking voltage to the end effector to activate the electrostatic chuck.

A method of activating an electrostatic chuck includes manufacturing an electrical generator to activate an electrostatic chuck and further, manufacturing an end effector comprising the electrostatic chuck. The method further includes electrically coupling the end effector to the electrical generator.

A dual arm robot includes an end effector. The end effector includes a first layer that comprises aluminum oxide. The end effector further includes a second layer having a first area with positive electrodes and a second area with negative electrodes, wherein the second layer is deposited over the first layer, and wherein the second layer comprises molybdenum. The end effector also includes a third layer deposited over the second layer, wherein the third layer comprises silicon oxide. The end effector finally includes a fourth layer deposited over the third layer, wherein the fourth layer comprises mesas composed of silicon oxide to reduce backside particle contamination. The dual arm also includes an internal electrical generation system that includes a pair of stacked dual arms, wherein the pair comprises an upper arm and a lower arm. The internal electrical generation system also includes a set of wound electrical coils mounted to the upper arm. The internal electrical generation system further includes a set of magnets mounted to the lower arm. The relative motion between the upper arm and the lower arm induces current used to generate electrostatic force in the end effector.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 illustrates a top view of a dual arm robot in a wafer processing system in accordance with exemplary embodiments of the disclosure;

FIG. 2 illustrates a cross-sectional view of an end effector in dual arm robot of FIG. 1 in accordance with exemplary embodiments of the disclosure;

FIG. 3 illustrates a top view of end effector in dual arm robot of FIG. 1 in accordance with exemplary embodiments of the disclosure;

FIG. 4 illustrates one embodiment of an electrical generation system to generate electrostatic force in end effector in dual arm robot of FIG. 1 in accordance with exemplary embodiments of the disclosure;

FIG. 5 illustrates another embodiment of an electrical generation system to generate electrostatic force in end effector in dual arm robot of FIG. 1 in accordance with exemplary embodiments of the disclosure;

FIG. 6 illustrates another embodiment of an electrical generation system to generate electrostatic force in end effector in dual arm robot of FIG. 1 in accordance with exemplary embodiments of the disclosure; and

FIG. 7 illustrates a flow diagram of a method for manufacturing an end effector and an electrical generation system to activate the end effector such as one in dual arm robot of FIG. 1 in accordance with exemplary embodiments of the disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

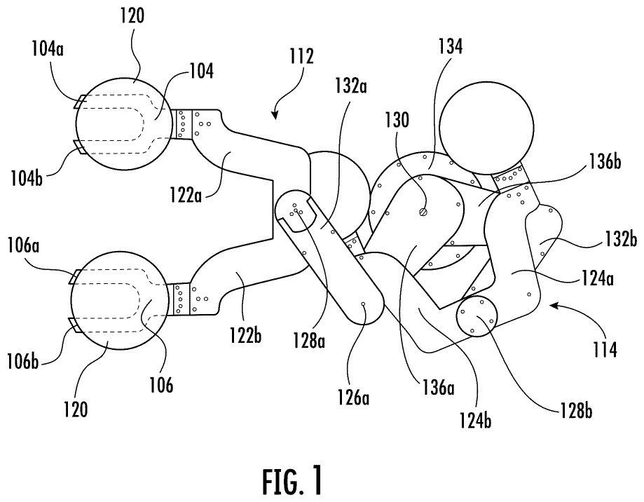

Referring to FIG. 1, a dual arm substrate handling robot 100 is illustrated. Substrate handling robot 100 is generally used in a substrate processing system. The substrate processing system may include a Front Opening Unified Pod (FOUP), an equipment front end module (EFEM), a load lock chamber, a substrate handling chamber, and one or more processing modules. Generally, unprocessed wafers are accessed by the substrate processing system in FOUP. The EFEM includes a front end robot that is configured to obtain wafers from the FOUP and readied to be transported to the load lock chamber. The transfer of wafers from load lock chamber to a processing module is handled by a dual arm robot 100 in the substrate handling chamber. The substrate handling chamber may be a vacuum chamber. Accordingly, dual arm substrate handling robot 100 operates in a vacuum environment. The interior of each of the processing modules and the load lock chamber may be isolated from the interior of the substrate handling chamber by a gate valve.

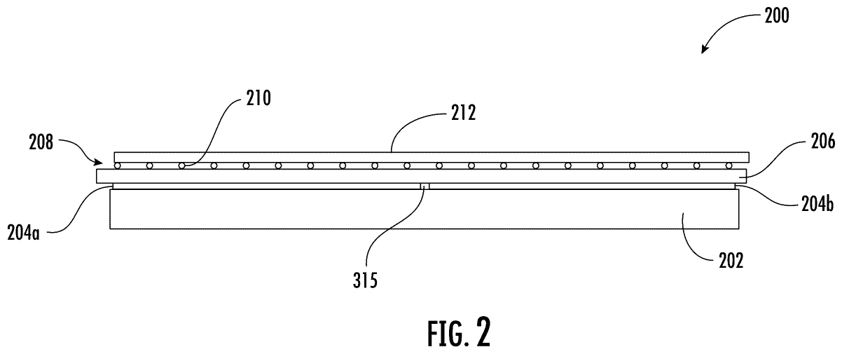

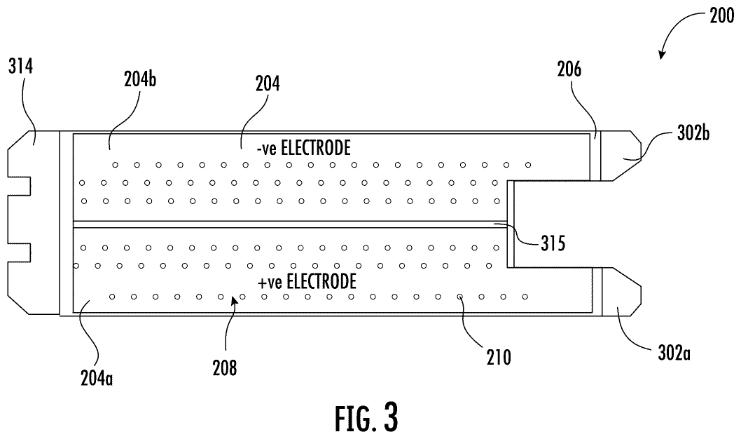

As shown in FIG. 1, dual arm robot 100 includes an upper arm 112 and a lower arm 114. Upper arm 112 includes an upper fork shaped section having a first fork 122a and a second fork 122b. Each of the forks 122a and 122b are further attached to end effectors 104 and 106, respectively. End effectors 104 and 106 are configured to support substrates 120 thereon. As shown in FIG. 1, end effector 104 includes two fingers 104a and 104b protruding out at the end of end effector 104. Similarly, end effector 106 also includes two fingers 106a and 106b protruding out at the end of end effector 106. Fabrication of end effectors 104 and 106 is described in further detail in FIGS. 2 and 3.

Upper arm 112 further includes an upper middle section 132a which is connected to the fork shaped section 122 via joint 128a. Upper arm 112 further includes an upper bottom section 136a which is connected to upper middle section 132a via joint 126a. Similarly, lower arm 114 includes a lower middle section 132b which is connected to a fork shaped section 124 of lower arm 114 via joint 128b. Further, similar to upper arm 112, lower arm 114 includes a lower bottom section 136b which is connected to lower middle section 132b via joint 126b. Arms 112 and 114 are further connected to an actuator 134 (and to each other) at joint 130. Lower arm 114 includes two end effectors, similar to end effectors 104 and 106, that are configured to support substrates, such as substrates 120. And further, each of the end effectors include two fingers protruding out at the end of end effector.

FIG. 2 illustrates a cross-sectional view of end effector 200, and FIG. 3 illustrates a top view of end effector 200. End effector 200 may be either of the end effectors described in FIG. 1 (such as end effectors 104 and 106). End effector 200 includes a first layer 202. In exemplary embodiments, first layer 202 is composed of any conventional substrate material (for example, Aluminum Oxide (Al₂O₃)). The first layer also forms fingers 302a and 302b of end effector 200. End effector 200 further includes an end section 314 that is configured to couple with arms, such as arms 112 and 114 of FIG. 1.

End effector 200 further includes a second layer 204 that is deposited on top of first layer 202. Second layer 204 includes two different sections 204a and 204b. A first section 204a is composed of positive electrode layer and second section 204b is composed of negative electrode layer. As shown in FIG. 3, positive electrode layer is deposited on approximately one section of end effector 200 such that the positive electrode layer is deposited on at least a part of finger 302a. Similarly, negative electrode layer is deposited on a second section of end effector 200 such that the negative electrode layer is deposited on at least part of finger 302b. The positive electrode layer 204a and the negative electrode layer 204b are approximately equal in area and volume to each other. Further, as shown in FIGS. 2 and 3, layers 204a and 204b are electrically separated from each other by a small separation distance 315. In exemplary embodiments, second layer 204 is composed of at least one of tungsten, titanium or molybdenum. In exemplary embodiments, second layer 204 may be any other appropriate conductive material. Accordingly, second layer 204 forms a metallized film with equal areas to form opposite electrodes.

End effector 200 further includes a third layer 206 that is deposited on top of second layer 204. Third layer 206 may be composed of a dielectric material. In exemplary embodiments, this dielectric material may include an oxide (such as, silicon oxide). In exemplary embodiments, the thickness of third layer 206 is in a range of 100 to 200 microns inclusive.

End effector 200 further includes a fourth layer 208 that is deposited on top of third layer 206. Fourth layer 208 includes mesas 210 to minimize the amount of contact between wafer 212 and third layer 206. Mesas 210 may be dots of silicon oxide deposited on top of third layer 206. In exemplary embodiments, these dots of mesas 210 are 1 millimeter in diameter and 5 microns in height. In exemplary embodiments, these mesas 210 may be created using physical vapor deposition (PVD) technology or any other alternative conventional technology. Reducing the contact between wafer 212 and layer 206 results in a reduction in backside particle contamination as wafer 212 is received by end effector 200. Fabrication of end effector 200 as discussed herein results in generation of an electrostatic force that assists in holding the wafer in place during motion.

When end effector 200 is charged, it provides an electrostatic force. This electrostatic force in addition to gravitational force and frictional forces resulting from the placement of wafer 212 on end effector 200 can be combined to counter centrifugal force that results when dual arm robot 100 is in motion. End effector 200 may be charged using external power sources or an internal electrical generation system.

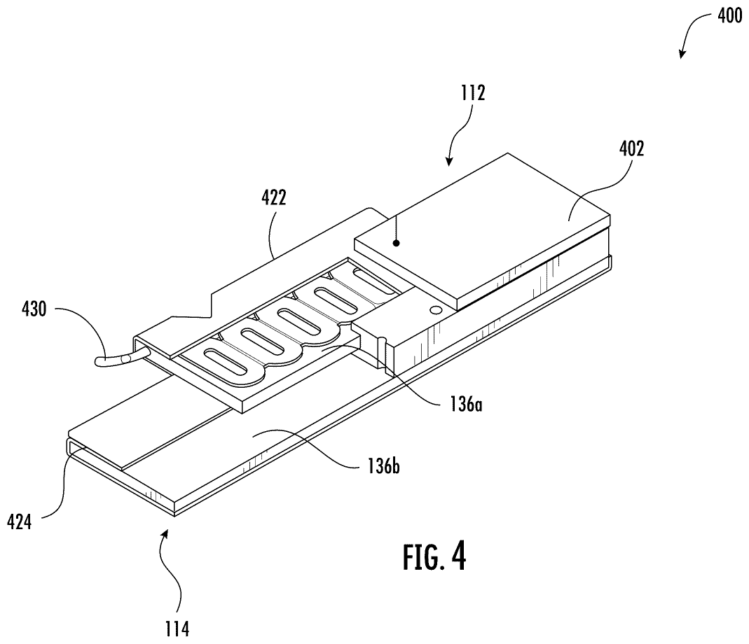

FIGS. 4-6 illustrate various exemplary embodiments of voltage generation systems to power end effector 200. FIG. 4 illustrates one embodiment of an electrical generator 400 in accordance with the embodiments described herein. Electrical generator 400 may be implemented in a dual arm robot, such as dual arm robot 100 described in FIG. 1. Electrical generator 400 includes a set of wound electrical coils 422, which is mounted to upper arm 112. Electrical generator 400 further includes a set of corresponding magnets 424, which is mounted to lower arm 114. As shown in FIG. 4, set of electrical coils 422 is facing down and set of corresponding magnets 424 is facing up. These sets of electrical coils 422 and corresponding magnets 424 are inserted in the gap between lower arm 114 and upper arm 112. Further, in exemplary embodiments, set of electrical coils 422 is mounted to upper arm 112 at upper bottom section 136a. In exemplary embodiments, set of corresponding magnets 424 is mounted to lower arm 114 at lower bottom section 136b.

Accordingly, any relative motion between upper arm 112 and lower arm 114 induces voltage in the set of electrical coils 422 when it is within a magnetic field. For example, this relative motion may be a linear motion as the upper arm and the lower arm moved forward and backward. In some examples, the relative motion may be a rotary motion as the upper and the lower arm are moving in a rotational manner along one or more joints 126a, 128a, 126b, 128b or 130. This voltage may be stored that may then be used to power end effector 200. Thus, every time dual arm robot 100 moves, the kinetic energy generated by the motion can be converted and utilized as electrical energy that may be used as electrostatic force by end effector 200. That is, higher robot acceleration results in a higher electrostatic force. Consequently, dual arm robot 100 can move at an increased speed while still holding substrate 120 in place.

In exemplary embodiments, an electrical generator similar to electrical generator 400 is placed at any one or more joints 126a, 126b, 128a, 128b and 130. Accordingly, every time motion is detected at any of these joints, the mechanical energy generated from the motion can be transferred into electrical energy that can be used as electrostatic force by end effector 200. In exemplary embodiments, an electrical generator similar to electrical generator 400 is placed at any one or more sections of dual arm robot 100. For example, set of electrical coils 422 can be placed on any one of the sections 124a, 124b, 132a, 136a. Similarly, set of magnets 424 can be placed in any of one of the section 124a, 124b, 132b, 136b. Accordingly, every time upper arm 112 moves relative to lower arm 114, such that the electrical coils 422 are in the magnetic field generated by magnets 424, the mechanical energy generated from the relative motion can be converted into electrical energy that can be used by end effector 200 to generate an electrostatic force.

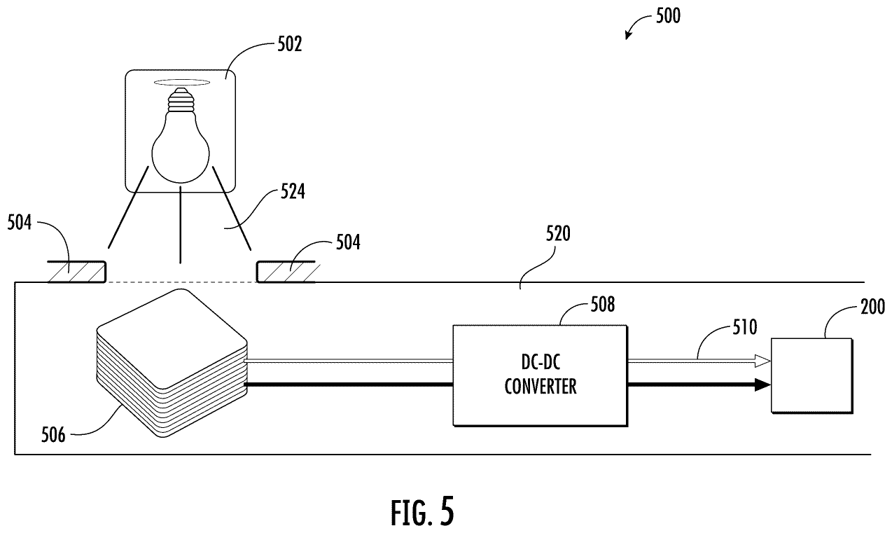

FIG. 5 illustrates one embodiment of an electrical generation system 500. Electrical generation system 500 includes a light source 502. As shown in FIG. 5, light source 502 is located outside chamber 520. In exemplary embodiments, chamber 520 is a substrate handling chamber that includes dual arm robot 100. Light source 502 is configured to project light 524 into chamber 520 through a chamber window 504. In exemplary embodiments, chamber window 504 is composed of a material (such as, glass) that allows light 524 to pass through into chamber 520.

Light 524 is received and processed by a DC voltage generator 506. In exemplary embodiments, DC voltage generator 506 is composed of photovoltaic cells (for example, solar panel). DC voltage generator 506 is further electrically coupled to a DC-DC converter 508. DC-DC converter 508 is further electrically coupled (510) to end effector 200. Accordingly, resulting voltage from DC voltage generator 506 is converted to a voltage level that can be utilized by end effector 200 to generate electrostatic force.

In exemplary embodiments, at least a portion of substrate handling chamber 520 is composed of light reflective surfaces (such as, aluminum). Accordingly, in some exemplary embodiments, any light illuminated inside the chamber may be bounced back and forth through the chamber until it impinges photovoltaic cells of DC voltage generator 506. Further, in exemplary embodiments, substrate handling chamber 520 may include nickel plating to enhance the probability of light reflection inside chamber 520 and impingement at the surface of photovoltaic cells of DC voltage generator 506 providing a continuous source of voltage generation that can be utilized by end effector 200.

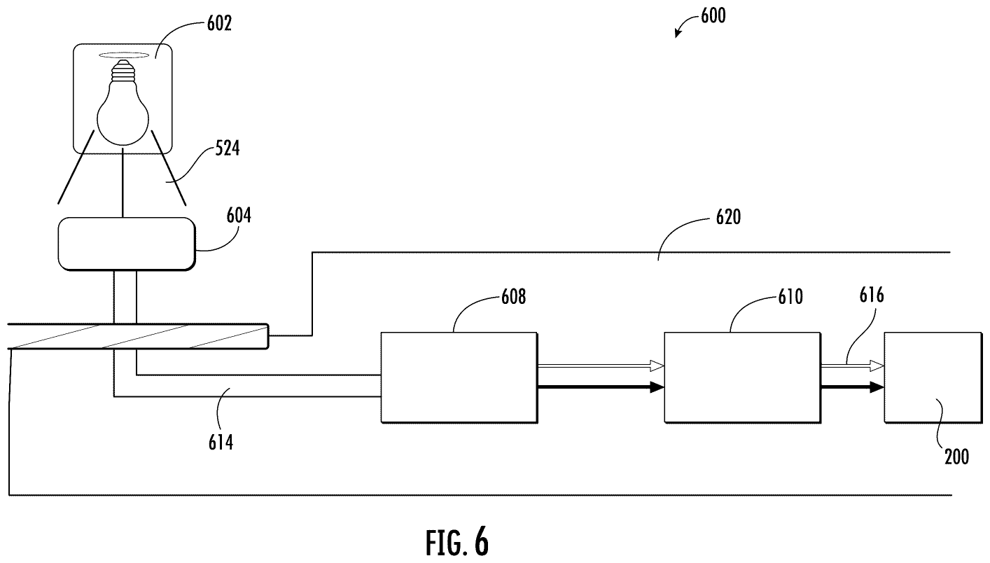

FIG. 6 illustrates one embodiment of an electrical generation system 600. Electrical generation system 600 includes a mono-chromatic laser source 602. In exemplary embodiments, wavelength of laser right transmitted from source 602 is within a range of 400 to 1600 nanometers. Electrical generation system 600 further includes a light receiver 604 and a chamber 620. In exemplary embodiments, chamber 620 is a substrate handling chamber that includes dual arm robot 100. In exemplary embodiments, light receiver 604 is located outside chamber 620. Laser(s) 624 projected by source 602 are received by light receiver 604.

Light receiver 604 is further coupled to a laser-electricity converter 608. In exemplary embodiments, light receiver 604 is coupled to laser-electricity converter 608 using an optical fiber 614. Laser-electricity converter 608 is configured to receive laser light 624 through optical fiber 614. Further, laser-electricity converter 608 is configured to convert this laser light 624 to electrical energy. In exemplary embodiments, laser-electricity converter 608 is located inside substrate handling chamber 620.

Electrical generation system 600 further includes a DC-DC converter 610 that is electrically coupled to laser-electricity converter 608. DC-DC converter 610 is further electrically coupled (616) to end effector 200. Accordingly, electrical energy generated by laser-electricity converter 608 is further converted to a voltage level that can be utilized by end effector 200 to generated electrostatic force.

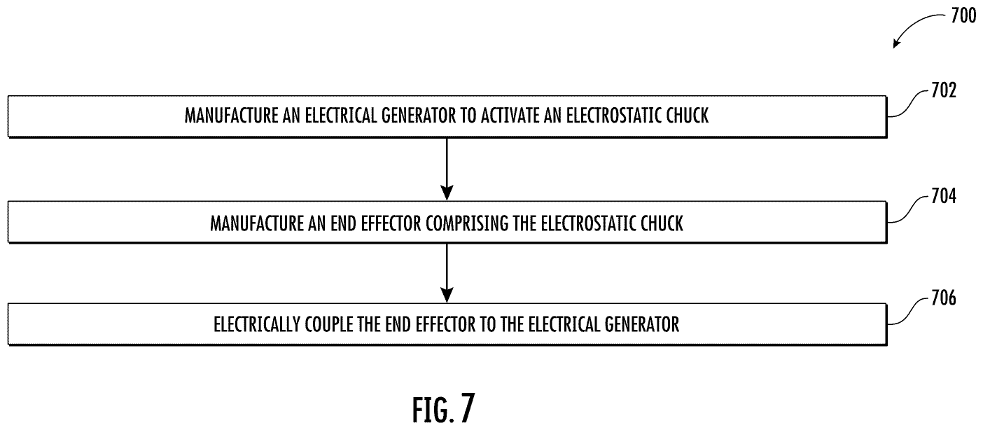

FIG. 7 illustrates a method 700 of activating an electrostatic chuck in a dual arm robot, e.g. dual arm robot 100. Method 700 includes manufacturing an end effector, such as end effector 200, as shown with box 702. In exemplary embodiments, manufacturing an end effector includes depositing a first layer comprising aluminum oxide (such as, first layer 202). Further, manufacturing an end effector also includes depositing a second layer over of the first layer, the second layer having a first area with positive electrodes and a second area with negative electrodes (such as second layer 204). Manufacturing an end effector also includes depositing a third layer over of the second layer, wherein the third layer is composed of dielectric material (such as layer 206). In exemplary embodiments, the dielectric material may be silicon oxide. In further exemplary embodiments, third layer may have a thickness in a range of 100 microns to 200 microns. Finally, manufacturing an end effector may also include depositing a fourth layer over the third layer such that the fourth layer comprises mesas to reduce backside particle contamination (such as layer 208). In exemplary embodiments, these mesas may have a diameter of 1 mm and a height of 5 microns. Further, these mesas may be deposited using physical vapor deposition technique.

Method 700 further includes manufacturing an electrical generator to activate the electrostatic chuck, shown with box 704. In exemplary embodiments, manufacturing an electrical generator includes utilizing an upper arm and a lower arm of the dual arm robot to activate the electrostatic chuck (such as electrical generator 400). Manufacturing such a generator includes mounting at least one set of wound coils (such as electrical coils 422) to an upper arm in a gap of a pair of stacked dual arms in a vacuum robot. Manufacturing such a generator further includes mounting at least one set of magnets (such as magnets 424) to a lower arm in a gap of the pair of stacked dual arms in the vacuum robot. In exemplary embodiments, the gap is at a joint connecting the upper arm and the lower arm. Further, manufacturing such a generator further includes converting the energy generated by the relative motion between the upper arm and the lower arm into current that may be used to activate the electrostatic chuck. For example, this relative motion may be a linear motion as the upper arm and the lower arm moved forward and backward. In some examples, the relative motion may be a rotary motion as the upper and the lower arm are moving in a rotational manner along one or more joints 126a, 128a, 126b, 128b or 130.

In exemplary embodiments, manufacturing an electrical generator includes utilizing a laser source to activate the electrostatic chuck (such as electrical generation system 500). Manufacturing such a generator includes coupling the electrostatic chuck to a laser-electricity converter (such as converter 608). Manufacturing such a generator further includes coupling the laser-electricity converter to a light receiver using an optical fiber (such as optical fiber 614), such that the light received by the converter is converted to electrical energy used to activate the electrostatic chuck. Further, manufacturing such a generator includes coupling the light receiver and a laser source (such as source 602) wherein the laser source is configured to provide a monochromatic laser to the light receiver.

In exemplary embodiments, manufacturing an electrical generator includes utilizing a light source to activate the electrostatic chuck (such as electrical generation system 600). Manufacturing such a generator includes coupling the electrostatic chuck to a voltage generator (such as DC voltage generator 506). Manufacturing such a generator further includes coupling the voltage generator to a light source (such as light source 502), wherein the voltage generator comprises photovoltaic cells. In exemplary embodiments, the voltage generator comprises one or more solar cells.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A vacuum robot comprises:
an end effector comprising an electrostatic chuck; and
an electrical generator coupled to the end effector to provide a chucking voltage to the end effector to activate the electrostatic chuck.

2. The vacuum robot of claim 1, wherein the end effector further comprises:
a first layer composed of a substrate material;
a second layer having a first area with positive electrodes and a second area with negative electrodes, wherein the second layer is deposited over the first layer;
a third layer composed of dielectric material, wherein the third layer is deposited over the second layer;
a fourth layer comprising mesas to reduce backside particle contamination, wherein the fourth layer is deposited over the third layer.

3. The vacuum robot of claim 2, wherein the substrate material comprises aluminum oxide.

4. The vacuum robot of claim 2, wherein the fourth layer comprises mesas having a diameter of 1 mm and height of 5 μm.

5. The vacuum robot of claim 2, comprising a first end and a second end, wherein the first end comprises the first area and the second end comprises the second area.

6. The vacuum robot of claim 2, wherein the third layer has a thickness within a range of 100 μm to 200 μm.

7. The vacuum robot of claim 1, comprises:
a pair of stacked dual arms, wherein the pair comprises an upper arm, a lower arm and a joint connecting the upper arm and the lower arm such that the joint results in a gap between the upper arm and the lower arm; and
wherein the electrical generator comprises:
at least one set of wound coils mounted to the upper arm;
at least one set of magnets mounted to the lower arm; and
at least one converter such that relative motion between the upper arm and the lower arm induces current used to activate the electrostatic chuck.

8. The vacuum robot of claim 1, wherein the relative motion between the upper arm and the lower arm is revolute joint motion.

9. The vacuum robot of claim 1, wherein the electrical generator comprises:
at least one set of wound coils mounted to a first section of the vacuum robot;
at least one set of magnets mounted to a second section of the vacuum robot; and
wherein the relative motion between the first section and the second section induces voltage in the at least one set of electrical coils when it is within a magnetic field resultant from the at least one set of magnets.

10. The vacuum robot of claim 1, wherein the electrical generator comprises:
a laser source;
a light receiver located within a chamber comprising the vacuum robot, wherein the light receiver is coupled to the laser source and is configured to receive light energy transmitted by the laser source;
a laser-electricity converter coupled to the light receiver, wherein the laser electricity converter is configured to convert light energy into electrical energy used to activate the electrostatic chuck.

11. The vacuum robot of claim 10, wherein the light receiver and the laser electricity converter are coupled by an optical fiber.

12. The vacuum robot of claim 1, wherein the electrical generator comprises:
a light source;
a voltage generator configured to receive light from the light source and generate voltage based on the light from the light source;
a DC-DC converter coupled to the voltage generator and the electrostatic chuck, such that the DC-DC converter is configured to convert the voltage used to activate the electrostatic chuck.

13. A method of activating an electrostatic chuck comprising:
manufacturing an electrical generator to activate an electrostatic chuck;
manufacturing an end effector comprising the electrostatic chuck; and
electrically coupling the end effector to the electrical generator.

14. The method of claim 11, wherein manufacturing the end effector, further comprising:
depositing a first layer comprising aluminum oxide;
depositing a second layer over of the first layer, the second layer having a first area with positive electrodes and a second area with negative electrodes;
depositing a third layer over of the second layer, wherein the third layer is composed of dielectric material;
depositing a fourth layer over the third layer, wherein the fourth layer comprises mesas to reduce backside particle contamination.

15. The method of claim 14, wherein the fourth layer comprises mesas having a diameter of 1 mm and height of 5 μm.

16. The method of claim 11, wherein manufacturing the electrical generator to activate the electrostatic chuck, comprises:
mounting at least one set of wound coils to an upper arm in a gap of a pair of stacked dual arms in a vacuum robot;
mounting at least one set of magnets to a lower arm in the gap of the pair of stacked dual arms in the vacuum robot, wherein the gap is at a joint connecting the upper arm and the lower arm;
converting energy generated by relative motion between the upper arm and the lower arm into current used to activate the electrostatic chuck.

17. The method of claim 16, wherein manufacturing the electrical generator to activate the electrostatic chuck comprises:
coupling the end effector to a laser-electricity converter;
coupling the laser-electricity converter to a light receiver using an optical fiber, such that the light received by the laser-electricity converter is converted to electrical energy used to activate the electrostatic chuck;
coupling the light receiver and a laser source wherein the laser source is configured to provide a monochromatic laser to the light receiver.

18. The method of claim 16, wherein manufacturing an electrical generator to activate an electrostatic chuck comprises:
coupling the electrostatic chuck to a voltage generator;
coupling the voltage generator to a light source, wherein the voltage generator comprises photovoltaic cells.

19. The method of claim 16, wherein manufacturing the electrical generator to activate the electrostatic chuck comprises:
coupling the end effector to a DC-DC converter;
coupling the DC-DC converter to a voltage generator;
coupling the voltage generator and a light source, wherein light from the light source is received by the voltage generator through a transparent medium and generated into voltage by the voltage generator, wherein the voltage generated by the voltage generator is used to activate the electrostatic chuck.

20. A dual arm robot comprises:
an end effector comprising:
a first layer comprising aluminum oxide;
a second layer having a first area with positive electrodes and a second area with negative electrodes, wherein the second layer is deposited over the first layer, and wherein the second layer comprises molybdenum;
a third layer deposited over the second layer, wherein the third layer comprises silicon oxide; and
a fourth layer deposited over the third layer, wherein the fourth layer comprises mesas composed of silicon oxide to reduce backside particle contamination; and
an internal electrical generation system comprising:
a pair of stacked dual arms, wherein the pair comprises an upper arm and a lower arm;
a set of wound electrical coils mounted to the upper arm;
a set of magnets mounted to the lower arm; and
wherein relative motion between the upper arm and the lower arm induces current used to generate electrostatic force in the end effector.
